(19) United States
(12) Patent Application Publication
(10) Pub. No.: US 2021/0257586 A1
(43) Pub. Date: Aug. 19, 2021

(54) OLED DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Tianfu GUO, Wuhan, Hubei (CN)

(21) Appl. No.: 16/097,928

(22) PCT Filed: Sep. 3, 2018
(86) PCT No.: PCT/CN2018/103815

§ 371 Date: Oct. 31, 2018

(30) Foreign Application Priority Data
Aug. 9, 2018 (CN) 201810905040.9

(51) Int. Cl. H01L 51/52; H01L 51/56

(52) U.S. Cl. CPC H01L 51/5253; H01L 51/56

(57) ABSTRACT

The present application provides an organic light-emitting diode (OLED) display panel and a method of manufacturing thereof, the OLED display panel comprising an OLED substrate and an encapsulation portion disposed on the OLED substrate; wherein the OLED substrate comprises a substrate and an OLED layer disposed on the substrate; the substrate comprises a display region and an edge region surrounding the display region; the OLED layer is disposed in the display region; the encapsulation portion comprises a barrier body and an encapsulation layer; the barrier body is disposed in the edge region and comprises at least one barrier ring; the barrier ring surrounds the OLED layer and is disposed apart from the OLED layer, the encapsulation layer is disposed above the barrier body.

### FIELD OF APPLICATION

The present application relates to the field of display, and particularly to an OLED display panel and a manufacturing method thereof.

### DESCRIPTION OF PRIOR ART

Currently, organic light-emitting diode (OLED) screens, which are used widely in the display field, usually employ a top-emitting device structure. The OLED device consists of an anode, an organic layer, and a cathode, wherein the organic layer includes an electron hole injection layer, an electron hole transport layer, an organic light-emitting layer, an electron transport layer, and an electron injection layer.

Because the organic light-emitting layer and the cathode are very sensitive to water and oxygen, it is particularly important to prevent water and oxygen from invading the organic light-emitting layer in the OLED. Currently, thin film encapsulation (TFE) is used to protect OLED devices. For TFE technology, the most important things are its water-blocking performance and oxygen-blocking performance, and on this basis, the optical penetration and flexible bending properties of the TFE film layer should be taken into account as well. For OLED devices, the intrusion ways of external water and oxygen can be classified into two categories: by one way water and oxygen directly penetrate the TFT film layer from top to bottom and get into the OLED device, and by the other way water and oxygen penetrate the TFT film layer from the side of the TFE film and erode the OLED device. For current TFE structures, they usually prevent water and oxygen from eroding the OLED device through the first way, which resulting in water and oxygen to get into the OLED display panel through the second way and erode the OLED device. One conventional method for blocking the erosion of water and oxygen is to provide a dam-like structure on the periphery of the OLED device, but the dam-like structure requires a multi-mask process, which is complicated and has a high cost. Therefore, there is an urgent need for an OLED display panel that can protect the OLED device from the erosion of water and oxygen, while the manufacturing cost is low and the process is simple.

### SUMMARY OF THE APPLICATION

The application mainly provides an organic light-emitting diode (OLED) display panel and a manufacturing method thereof, to solve problems of the weak water-blocking and oxygen-blocking performances on the side, high cost and complicated process in current OLED display panel.

To achieve the above objects, the technical solution provided by the present application is as follows.

According to an aspect of the present application, an OLED display panel is provided, comprising an OLED substrate and an encapsulation portion disposed on the OLED substrate.

Wherein the OLED substrate comprises a substrate and an OLED layer disposed on the substrate; the substrate comprises a display region and an edge region surrounding the display region; the OLED layer is disposed in the display region.

The encapsulation portion comprises a barrier body and an encapsulation layer;

The barrier body is disposed in the edge region and comprises at least one barrier ring; the barrier ring surrounds the OLED layer and is disposed apart from the OLED layer; a height of the barrier ring ranges from 0.5 micrometers to 5 micrometers.

The encapsulation layer is disposed on the barrier body.

According to an embodiment of the present application, the barrier body is annularly disposed in the edge region, and a number of the barrier rings is greater than or equal to two.

According to an embodiment of the present application, the barrier body is disposed in a spiral shape on the edge region, and a number of spiral rounds of the barrier ring is greater than or equal to two.

According to an embodiment of the present application, the adjacent barrier rings are spaced apart from each other; the height of the barrier ring gradually increases along a direction from the edge region to the display region.

According to an embodiment of the present application, the encapsulation portion comprises a first inorganic layer, a second inorganic layer, an organic layer and a third inorganic layer which are sequentially stacked; the first inorganic layer is disposed above the barrier body and covers the OLED layer and the barrier body.

According to another aspect of the present application, a method of manufacturing an OLED display panel is provided, which comprises:

Step S10, providing an OLED substrate, wherein the OLED substrate comprises a substrate and an OLED layer disposed on the substrate; the substrate comprises a display region and an edge region surrounding the display region; the OLED layer is disposed in the display region;

Step S20, forming a barrier body in the edge region, wherein the barrier body surrounds the OLED layer and is disposed apart from the OLED layer; the barrier body comprises at least one barrier ring;

Step S30, forming an encapsulation layer on the OLED substrate, wherein the barrier body comprises at least one barrier ring.

According to an embodiment of the present application, the step S20 comprises: forming at least one ring of barrier liquid using an inkjet printing technique in the edge region, and curing the barrier liquid to form the barrier ring by ultraviolet rays.

According to an embodiment of the present application, the barrier body is annularly disposed in the edge region, and a number of the barrier ring is greater than or equal to two.

According to an embodiment of the present application, the encapsulation layer comprises a first inorganic layer, a second inorganic layer, an organic layer and a third inorganic layer, which are sequentially stacked; the step S30 comprises forming a first inorganic layer over the barrier body by an atomic layer deposition technique.

According to another aspect of the present application, an OLED display panel is provided, which comprises an OLED substrate and a encapsulation portion disposed on the OLED substrate.

Wherein the OLED substrate comprises a substrate and an OLED layer disposed on the substrate; the substrate comprises a display region and an edge region surrounding the display region; the OLED layer is disposed in the display region.

The encapsulation portion comprises a barrier body and an encapsulation layer.

The barrier body is disposed in the edge region, and comprises at least one barrier ring; the barrier ring surrounds the OLED layer and is disposed apart from the OLED layer.

The encapsulation layer is disposed on the barrier body.

According to an embodiment of the present application, the barrier body is annularly disposed in the edge region, and a number of the barrier rings is greater than or equal to two.

According to an embodiment of the present application, the barrier body is disposed in a spiral shape on the edge region, and a number of spiral rounds of the barrier ring is greater than or equal to two.

According to an embodiment of the present application, the adjacent barrier rings are spaced apart from each other; the heights of the barrier rings gradually increase along a direction from the edge region to the display region.

According to an embodiment of the present application, the encapsulation layer comprises a first inorganic layer, a second inorganic layer, an organic layer and a third inorganic layer which are sequentially stacked; the first inorganic layer is disposed above the barrier body and covers the OLED layer and the barrier body.

The advantages of the present application include: providing an OLED display panel and a manufacturing method thereof, the barrier body and the inorganic layer are combined by providing a barrier body including at least one round of a barrier ring in the edge region of the OLED substrate to enhance the side water-blocking performance and oxygen-blocking performance of the OLED display panel. In this way, the multi-layer mask process is avoided, and the manufacturing process of the OLED display panel is simplified on the basis of improving the water-blocking performance and oxygen-blocking performance of the package structure.

### BRIEF DESCRIPTION OF DRAWINGS

In order to describe clearly the embodiment in the present disclosure or the prior art, the following will introduce the drawings for the embodiment shortly. Obviously, the following description is only a few embodiments, for the common technical personnel in the field it is easy to acquire some other drawings without creative work.

FIG. 1 is a structure diagram of an OLED display panel according to an embodiment of the present application;

FIG. 2 is a structure diagram of an OLED display panel according to another embodiment of the present application;

FIG. 3 is a structure diagram of a barrier body according to an embodiment of the present application;

FIG. 4 is a top view of a barrier body according to an embodiment of the present application;

FIG. 5 is a top view of a barrier body according to another embodiment of the present application;

FIG. 6A-6B are structure diagrams of a encapsulation portion according to an embodiment of the present application;

FIG. 7 is a flow chart of a method for manufacturing an OLED display panel according to an embodiment of the application;

FIG. 8A-8C are structure diagrams of a method of manufacturing an OLED display panel according to an embodiment of the application.

### DETAILED DESCRIPTION OF PREFERRED EMBODIMENTS

The description of following embodiment, with reference to the accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present disclosure. In the drawings, the components having similar structures are denoted by same numerals.

The application aims to solve problems of the weak water-blocking and oxygen-blocking performances on the side, high cost and complicated process in current OLED display panel, and provides an OLED display panel and a manufacturing method thereof, the provided embodiments can improve the defects.

The present application will be further described below combining with the accompanying drawings and specific embodiments.

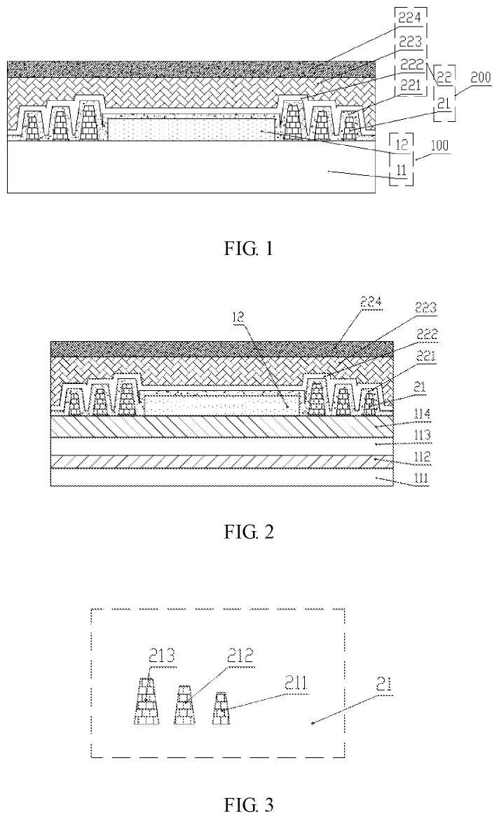

As shown in FIG. 1, the present application provides an OLED display panel, comprising an OLED substrate 100 and an encapsulation portion 200 disposed on the OLED substrate.

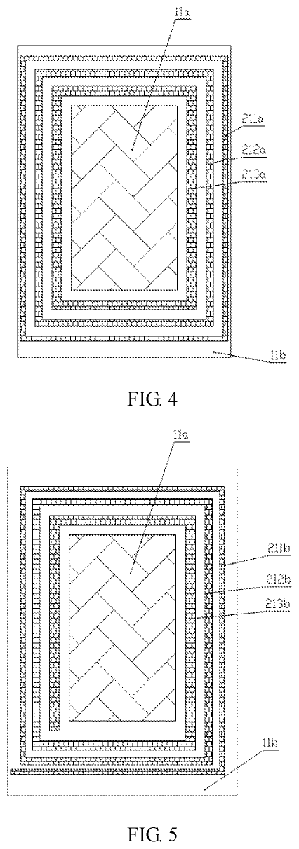

As shown in FIG. 4, the OLED substrate 100 comprises a substrate 11 and an OLED layer disposed on the substrate; the substrate 11 comprises a display region 11a and an edge region 11b surrounding the display region 11a; the OLED layer 12 is disposed in the display region 11b.

The encapsulation portion 200 comprises a barrier body 21 and an encapsulation layer 22.

The barrier body 21 is disposed in the edge region 11b and comprises at least one barrier ring; the barrier ring surrounds the OLED layer 12 and is disposed apart from the OLED layer 12.

The encapsulation layer 22 is disposed on the barrier body 21.

Further, as shown in FIG. 2, the substrate 11 includes a glass substrate 111, a flexible substrate layer 112, a buffer layer 113, and a thin film transistor layer 114 which are sequentially stacked. It should be noted that, in some embodiments, the substrate 11 may not include the glass substrate 111.

Specifically, before the manufacturing process is performed on the glass substrate 111, the glass substrate 111 needs to be cleaned. The material of the flexible substrate layer 112 can be polyimide. The buffer layer 113 is made of one of silicon nitride and silicon oxide. The thin film transistor layer 114 includes an array of thin film transistors and metal traces. The OLED layer 12 is composed of an anode, an organic light-emitting layer, and a cathode. The organic light-emitting layer includes an electron hole injection layer, an electron hole transport layer, an organic light-emitting layer, an electron transport layer, and an electron injection layer.

Preferably, as shown in FIG. 4, the barrier body 21 is disposed in a spiral shape on the edge region 11b, and a number of spiral rounds of the barrier ring is greater than or equal to two.

Wherein the adjacent barrier rings are separated from each other to achieve a multi-round barrier effect on the side of the OLED display panel to improve the water-blocking and oxygen-blocking abilities of the OLED display panel.

The present application is mainly described by taking a barrier ring with a three-round barrier body as an example. As shown in FIG. 3, the barrier body 21 includes a first barrier ring 211, a second barrier ring 212, and a third barrier ring 213.

Preferably, as shown in FIG. 5, the barrier body 21 is disposed in a spiral shape on the edge region, and a number of spiral rounds of the barrier ring is greater than or equal to two, and the barrier rings are separated from each other.

Preferably, the height of the barrier body 21 ranges from 0.5 micrometers to 5 micrometers, thereby preventing the bulk of the barrier body 21 from having an influence on the structure of the OLED display panel.

Further, the adjacent barrier rings are spaced apart from each other.

As shown in FIG. 3, the heights of the barrier rings gradually increase along a direction from the edge region to the display region. The height of the first barrier ring 211<the height of the second barrier ring 212<the height of the third barrier ring. The volumes of the barrier rings gradually increase along a direction of the edge region to the display region, that is, the volume of the first barrier ring 211<the volume of the second barrier ring 212<the volume of the third barrier ring 213.

Through the differential setting of the barrier ring, an optimal design of the OLED display panel with a great the water-blocking property and oxygen-blocking property can be achieved. Since the heights of the second barrier ring 212 and the third barrier ring 213 are both larger than the first blocking ring 211, when water and oxygen from outside enter from the outermost first barrier ring 211, they are difficult to enter the second barrier ring 212 and the third barrier ring 213 due to the differences in height between the barrier rings.

Further, the encapsulation layer 22 comprises a first inorganic layer 221, a second inorganic layer 222, an organic layer 223 and a third inorganic layer 224 which are sequentially stacked.

The first inorganic layer 221 is disposed above the barrier body 21 and covers the OLED layer 12 and the barrier body 21.

It should be understood that the second inorganic layer 222 is disposed above the first inorganic layer 221; the organic layer 223 is disposed above the second inorganic layer 222; and the third inorganic layer 224 is disposed above the second inorganic layer 222.

Wherein, the first inorganic layer 221 can be fabricated by atomic layer deposition technology. The first inorganic layer 221 can be in close contact with the surface of the barrier body 21, so that the barrier body 21 and the first inorganic layer 221 form a wall-like structure surrounding the OLED layer 12, preventing water and oxygen entering the OLED display panel from side and eroding the OLED layer 15.

The second inorganic layer 222 and the third inorganic layer 224 are formed using at least one of a physical vapor deposition technique, a chemical vapor deposition technique, and an atomic layer deposition technique.

The materials of the first inorganic layer 221, the second inorganic layer 222, and the third electrodeless layer 224 are at least one of aluminum oxide, titanium oxide, and silicon oxide. Of course, the materials for preparing the first inorganic layer 221, the second inorganic layer 222, and the third electrodeless layer 224 are not limited to the above examples.

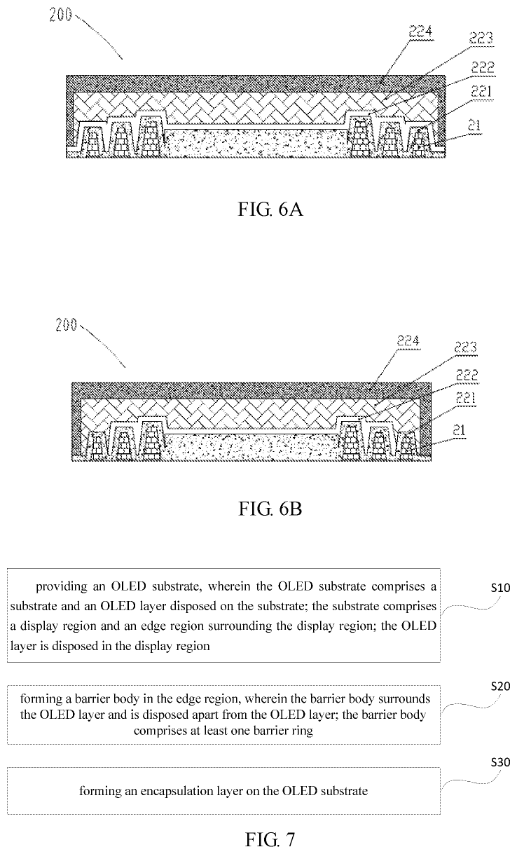

Generally, as shown in FIG. 6A, the second inorganic layer 222 covers the first inorganic layer 221. As shown in FIG. 6B, the second inorganic layer 222 only covers the barrier body 21 and the first inorganic layer 221 corresponding to the upper portion of the OLED layer 12. Specifically, the structure of the corresponding second inorganic layer can be selected according to actual conditions.

As shown in FIG. 7, according to another aspect of the present application, a method of manufacturing an OLED display panel is provided, which comprises:

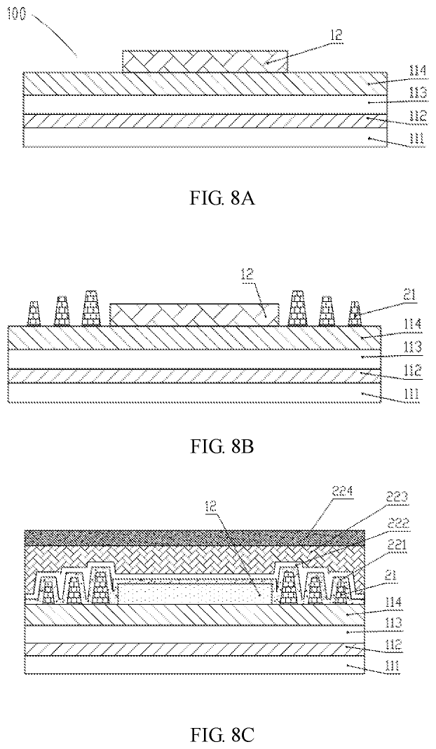

Step S10, as shown in FIG. 8A, providing an OLED substrate 100, wherein the OLED substrate 100 comprises a substrate 11 and an OLED layer 12 disposed on the substrate 11; the substrate 11 comprises a display region 11a and an edge region 11b surrounding the display region 11a; the OLED layer 12 is disposed in the display region 11a.

Specifically, the substrate 11 includes a glass substrate 111, a flexible substrate layer 112, a buffer layer 113, and a thin film transistor layer 114 which are sequentially stacked.

Step S20, as shown in FIG. 8B, forming a barrier body 21 in the edge region 11b, wherein the barrier body 21 surrounds the OLED layer 12 and is disposed apart from the OLED layer; the barrier body 21 comprises at least one barrier ring.

Preferably, the step S20 specifically includes: setting at least two barrier liquids on the surface of the OLED substrate 100 by inkjet printing, then curing the barrier liquid using ultraviolet rays light to form the barrier body 21, the barrier body 21 is disposed on the edge region 11b and surrounds the OLED layer 15.

In an embodiment, three circles of barrier liquid are disposed on the surface of the thin film transistor layer 14 by inkjet printing. This is because the package design of the three-round barrier body can achieve a balance between cost and water-blocking and oxygen-blocking capacity, and save cost while protect the OLED layer from water and oxygen. Hereinafter, the present application will be described with a three-ring barrier structure unless otherwise specified.

The main technical feature of the present application is that at least two ring-shaped barrier liquids are disposed on the periphery of the OLED layer by inkjet printing, and then the barrier body is formed by ultraviolet rays light curing. Compared with the corresponding structure processed by the existing mask process, the application can adjust the shape and position of the barrier body according to the actual situation, which greatly facilitates and simplifies the manufacture of the barrier body, and saves the cost of manufacturing an OLED display panel.

Step S30, as shown in FIG. 8C, forming an encapsulation layer 22 on the OLED substrate 100.

Preferably, the harrier body 21 includes a first barrier ring 211, a second barrier ring 212, and a third barrier ring 213.

Preferably, the barrier body 21 is formed in a square ring shape in the edge region 11b, and a number of rounds of the barrier rings is greater than or equal to 2.

Further, the encapsulation layer 22 includes a first inorganic layer 221, a second inorganic layer 222, an organic layer 223, and a third inorganic layer 224.

The step S30 includes forming the first inorganic layer 221 over the barrier body 21 by an atomic layer deposition technique, and the first inorganic layer 221 is attached to the surface of the barrier body 21.

The heights of the barrier rings gradually increase along a direction from the edge region to the display region. The volumes of the barrier rings gradually increase along a direction of the edge region to the display region.

The structure of the barrier body is as shown in FIG. 3. Along the direction from the edge region 14b to the display region 14a, the barrier body includes a first barrier ring 211, a second barrier ring 212 and a third barrier ring 213.

Preferably, the height of the barrier body 21 ranges from 0.5 micrometers to 5 micrometers.

Preferably, step S30 includes: forming a first inorganic layer 221 on the surface of the barrier body 21 by atomic layer deposition. The first inorganic layer 221 can be in close contact with the surface of the barrier body 21, so that the barrier body 21 and the first inorganic layer 221 can form a wall-like structure surrounding the OLED layer 15, preventing water and oxygen entering the OLED layer and eroding the OLED layer.

Further, in step S30, an organic layer 223 is formed on the surface of the second inorganic layer 222 by an inkjet printing technique and a chemical vapor deposition technique.

The organic layer 223 has the following three functions: 1. flattening the surface of the OLED layer 15 and the barrier body 21; 2. packaging foreign matter in the environment; 3. releasing stresses between the second inorganic layer 222 and the third inorganic layer 224.

The advantages of the present application include: providing an OLED display panel and a manufacturing method thereof, the barrier body and the inorganic layer are combined by providing a barrier body including at least one round of a barrier ring in the edge region of the OLED substrate to enhance the side water-blocking performance and oxygen-blocking performance of the OLED display panel. In this way, the multi-layer mask process is avoided, and the manufacturing process of the OLED display panel is simplified on the basis of improving the water-blocking performance and oxygen-blocking performance of the package structure.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

1. An organic light-emitting diode (OLED) display panel, comprising an OLED substrate and an encapsulation portion disposed on the t) ED substrate; wherein
the OLED substrate comprises a substrate and an OLED layer disposed on the substrate; the substrate comprises a display region and an edge region surrounding the display region; the OLED layer is disposed in the display region;
the encapsulation portion comprises a barrier body and an encapsulation layer;
the barrier body is disposed in the edge region and comprises at least one barrier ring; the barrier ring surrounds the OLED layer and is disposed apart from the OLED layer; a height of the barrier ring ranges from 0.5 micrometers to 5 micrometers;
the encapsulation layer is disposed on the barrier body.

2. The OLED display panel according to claim 1, wherein the barrier body is annularly disposed in the edge region, and a number of the barrier rings is greater than or equal to two.

3. The OLED display panel according to claim 1, wherein the barrier body is disposed in a spiral shape on the edge region, and a number of spiral rounds of the barrier ring is greater than or equal to two.

4. The OILED display panel according to claim 2, wherein the adjacent barrier rings are spaced apart from each other;
the height of the barrier ring gradually become higher along the a direction from the edge region to the display region.

5. The OLED display panel according to claim 1, wherein the encapsulation layer comprises a first inorganic layer, a second inorganic layer, an organic layer and a third inorganic layer which are sequentially stacked;
the first inorganic layer is disposed above the barrier body and covers the OLED layer and the barrier body.

6. A method of manufacturing an organic light-emitting diode (OLED) display panel, wherein the method comprises:
Step S10, providing an OLED substrate, wherein the OLED substrate comprises a substrate and an OLED layer disposed on the substrate; the substrate comprises a display region and an edge region surrounding the display region; the OLED layer is disposed in the display region;
Step S20 forming a barrier body in the edge region, wherein the barrier body surrounds the OLED layer and is disposed apart from the OLED layer; the barrier body comprises at least one barrier ring;
Step S30, forming an encapsulation layer on the OLED substrate.

7. The method of manufacturing the OLED display panel according to claim 6, wherein the step S20 comprises: forming at least one ring of barrier liquid using an inkjet printing technique in the edge region, and curing the barrier liquid to form the barrier ring by ultraviolet rays.

8. The method of manufacturing the OLED display panel according to claim 6, wherein the barrier body is annularly disposed in the edge region, and a number of the barrier ring is greater than or equal to two.

9. The method of manufacturing the OLED display panel according to claim 6, wherein the encapsulation layer comprises a first inorganic layer, a second inorganic layer, an organic layer and a third inorganic layer which are sequentially stacked;
the step S30 comprises forming a first inorganic layer over the barrier body by an atomic layer deposition technique.

10. An organic light-emitting diode (OLED) display panel, comprising an OLED substrate and a encapsulation portion disposed on the MED substrate; wherein
the OLED substrate comprises a substrate and an OLED layer disposed on the substrate; the substrate comprises a display region and an edge region surrounding the display region; the OLED layer is disposed in the display region;
the encapsulation portion comprises a barrier body and an encapsulation layer;
the barrier body is disposed in the edge region, and comprises at least one barrier ring; the barrier ring surrounds the OLED layer and is disposed apart from the OLED layer;
the encapsulation layer is disposed on the barrier body.

11. The OLED display panel according to claim 10, wherein the barrier body is annularly disposed in the edge region, and a number of the barrier ring is greater than or equal to two.

12. The OLED display panel according to claim 10, wherein the barrier body is disposed in a spiral shape on the edge region, and a number of spiral rounds of the barrier ring is greater than or equal to two.

13. The OLED display panel according to claim 12, wherein the adjacent barrier rings are spaced apart from each other;
the height of the barrier ring gradually become higher along a direction from the edge region to the display region.

14. The OLED display panel according to claim 10, wherein the encapsulation layer comprises a first inorganic layer, a second inorganic layer, an organic layer and a third inorganic layer which are sequentially stacked;
the first inorganic layer is disposed above the barrier body and covers the OLED layer and the barrier body.
